(19) United States
(12) Patent Application Publication
(10) Pub. No.: US 2026/0148727 A1
(43) Pub. Date: May 28, 2026

(54) SOUND ABSORPTION STRUCTURE AND SERVER

(71) Applicants: INVENTEC (PUDONG) TECHNOLOGY CORPORATION, Shanghai (CN); INVENTEC CORPORATION, Taipei City (TW)

(72) Inventors: Hsin-Haou HUANG, Taipei City (TW); Teng-Shan HU, Taipei City (TW); Po-Hsiu CHEN, Taipei City (TW); Hsieh-Liang TSAI, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/232,140

(22) Filed: Jun. 9, 2025

(30) Foreign Application Priority Data
Nov. 25, 2024 (CN) 202411703096.8
Nov. 26, 2024 (CN) 202411715727.8

(51) Int. Cl. G10K 11/172; G10K 11/162; H05K 7/20

(52) U.S. Cl. CPC G10K 11/172; G10K 11/162; H05K 7/20136; H05K 7/20718

(57) ABSTRACT

A sound absorption structure includes at least one sound absorption unit. The sound absorption unit includes a plurality of sub units and a plurality of connection portions. The sub units are arranged in an array and connected to one another via the connection portions to surround a sound permeable slot together. Each of the sub units includes a sound absorption chamber, and the sound absorption chamber is a polygonal chamber. At least one of the sub units or at least one of the connection portions includes a connecting channel, and the sound absorption chamber communicates with the sound permeable slot through the connecting channel.

### CROSS-REFERENCE TO RELATED APPLICATIONS

This non-provisional application claims priority under 35 U.S.C. § 119(a) on Patent Application No(s). 202411703096.8 filed in China, on Nov. 25, 2024, and on Patent Application No(s). 202411715727.8 filed in China, on Nov. 26, 2024, the entire contents of which are hereby incorporated by reference.

### BACKGROUND OF THE INVENTION

### Technical Field of the Invention

The invention relates to a sound absorption structure and a server.

### Description of the Related Art

In response to the increasing computational demands, the performance of server continues to improve, which also results in significant heat generation. Fans, commonly used in thermal management systems, provide enhanced cooling performance but also lead to increased fan noise. Noise at specific frequencies may adversely affect the performance of storage device.

Currently, the most common noise reduction approach involves attaching low-cost passive noise reduction components to the inner side of the chassis and the backplane of the storage device to minimize the impact of noise on storage performance. However, the noise reduction effect of these components often falls short of expectations and fails to effectively mitigate noise in specific frequency bands, particularly those that are sensitive and likely to interfere with the read/write performance of the storage device. Therefore, researchers in this field are actively working to address the aforementioned issues.

### SUMMARY OF THE INVENTION

The invention provides a sound absorption structure and a server that can effectively prevent noise generated by the fan from affecting the performance of the storage device.

One embodiment of the invention provides a sound absorption structure. The sound absorption structure includes at least one sound absorption unit. The sound absorption unit includes a plurality of sub units and a plurality of connection portions. The sub units are arranged in an array and connected to one another via the connection portions to surround a sound permeable slot together. Each of the sub units includes a sound absorption chamber, and the sound absorption chamber is a polygonal chamber. At least one of the sub units or at least one of the connection portions includes a connecting channel, and the sound absorption chamber communicates with the sound permeable slot through the connecting channel.

Another embodiment of the invention provides a server. The server includes a casing, a hard disk module, a fan module and a sound absorption structure. The casing includes a hard disk storage area and a fan storage area. The hard disk module is disposed in the hard disk storage area. The fan module is disposed in the fan storage area. The sound absorption structure is disposed between the hard disk storage area and the fan storage area. The sound absorption structure includes at least one sound absorption unit. The sound absorption unit includes a plurality of sub units and a plurality of connection portions. The sub units are arranged in an array and connected to one another via the connection portions to surround a sound permeable slot together. Each of the sub units includes a sound absorption chamber, and the sound absorption chamber is a polygonal chamber. At least one of the sub units or at least one of the connection portions includes a connecting channel, and the sound absorption chamber communicates with the sound permeable slot through the connecting channel.

According to the sound absorption structure and the server as discussed in the above embodiments, the sound absorption structure is disposed between the hard disk storage area and the fan storage area, the sub units of the sound absorption unit of the sound absorption structure are arranged in the array and connected to one another to surround the sound permeable slot together, the sound absorption chamber of each sub unit is a polygonal chamber, and the connecting channels of the sub units respectively communicate with the sound absorption chambers of the sub units, and the sound absorption chamber of at least one of the sub units communicates with the sound permeable slot through the connecting channel. By the aforementioned configuration, when sound generated by the fan module enters the sound absorption chamber via the connecting channel of the sub unit, the sound waves cause resonance within the sound absorption chamber, converting sound energy into kinetic energy through resonance, thereby dissipating the sound. This effectively reduces the noise transmitted from the fan module to the hard disk module, preventing the noise from affecting the performance of the hard disk module.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a schematic view of a server according to a first embodiment of the invention;

FIG. 2 is a partial schematic view of a sound absorption structure in FIG. 1;

FIG. 3 is a schematic view of a sound absorption unit of the sound absorption structure in FIG. 2;

FIG. 4 is a schematic view of the deformed sound absorption unit in FIG. 3;

FIG. 5 is a schematic view of a sound absorption unit of a sound absorption structure according to a second embodiment of the invention;

FIG. 6 is a schematic view of the deformed sound absorption unit in FIG. 5.

FIG. 7 is a schematic view of a sound absorption unit of a sound absorption structure according to a third embodiment of the invention; and

FIG. 8 is a schematic view of the deformed sound absorption unit in FIG. 7.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

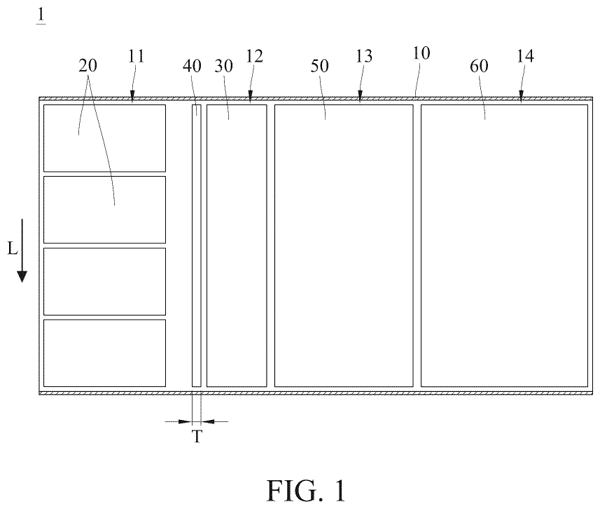

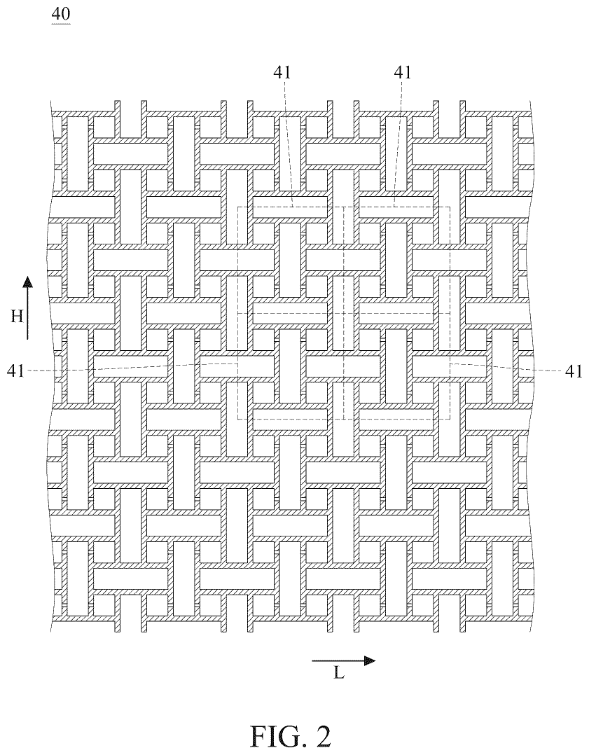

Referring to FIGS. 1 and 2, FIG. 1 is a schematic view of a server according to a first embodiment of the invention, and FIG. 2 is a partial schematic view of a sound absorption structure in FIG. 1.

In this embodiment, the server 1 includes a casing 10, at least one hard disk module 20, a fan module 30 and a sound absorption structure 40. In addition, the server 1 may further include a motherboard 50 and a power supply module 60.

The casing 10 includes a hard disk storage area 11, a fan storage area 12, a motherboard storage area 13 and a power supply storage area 14. The hard disk storage area 11, the fan storage area 12, the motherboard storage area 13 and the power supply storage area 14 are sequentially arranged along a lengthwise direction of the casing 10. The hard disk module 20, the fan module 30, the motherboard 50, and the power supply module 60 are respectively disposed in the hard disk storage area 11, the fan storage area 12, the motherboard storage area 13, and the power supply storage area 14. The sound absorption structure 40 is disposed in the casing 10 and located between the hard disk storage area 11 and the fan storage area 12.

The sound absorption structure 40, for example, is a single-piece planar auxetic metamaterial that utilizes precisely designed micro internal structures, rather than relying on the chemical composition of conventional materials, to achieve special physical properties (such as negative mass density, negative Poisson's ratio, and negative refractive index) to block sound waves of specific frequencies. The sound absorption structure 40 is, for example, elastically deformable along a lengthwise direction L and a heightwise direction H thereof, and a thickness T of the sound absorption structure 40 is, for example, greater than or equal to 5 mm and less than or equal to 10 mm. The sound absorption structure 40 includes a plurality of sound absorption units 41, which are arranged in an array and connected to one another. This configuration allows the sound absorption structure 40 to adjust its sound absorption performance by applying different strains, enabling effective noise reduction for different frequencies. Since the structures of these sound absorption units 41 are identical, only one of them is described in detail below.

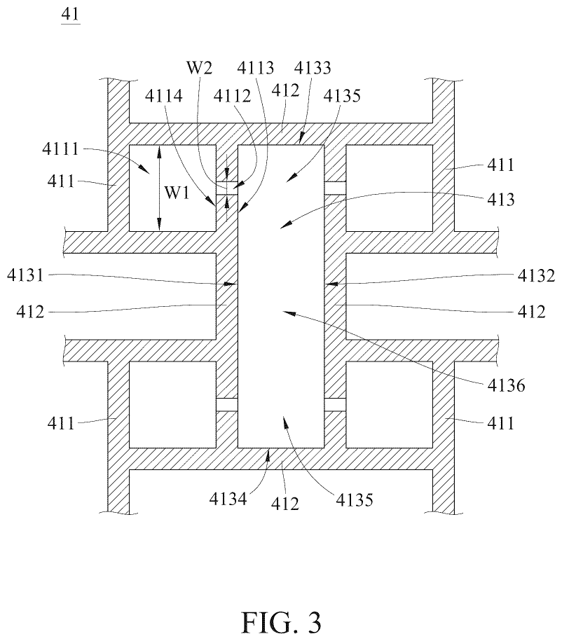

Then, referring to FIGS. 2 and 3, FIG. 3 is a schematic view of a sound absorption unit of the sound absorption structure in FIG. 2.

The sound absorption unit 41 includes a plurality of sub units 411 and a plurality of connection portions 412. The sub units 411 are arranged in an array and connected to one another via the connection portions 412 to surround a sound permeable slot 413 together. For example, the sound permeable slot 413 may be rectangular and include a first side 4131, a second side 4132, a third side 4133, a fourth side 4134, two end portions 4135 and a central portion 4136. The first side 4131 is located opposite to the second side 4132, and the third side 4133 is located opposite to the fourth side 4134. The two end portions 4135 and the central portion 4136 are located between the third side 4133 and the fourth side 4134, and the central portion 4136 is located between the two end portions 4135. The sound absorption unit 41 is, for example, a 20 mm×20 mm square and includes four sub units 411 and four connection portions 412, and the four sub units 411 are arranged in a 2×2 array. Two of the four sub units 411 and one of the four connection portions 412 are located at the first side 4131 of the sound permeable slot 413, and the others of the four sub units 411 and another of the four connection portion 412 are located at the second side 4132 of the sound permeable slot 413. The remaining two of the four connection portions 412 are located at the third side 4133 and the fourth side 4134 of the sound permeable slot 413, respectively.

Each of the sub units 411 includes a sound absorption chamber 4111 and a connecting channel 4112 communicating with each other, where the sound absorption chamber 4111 is a polygonal chamber, and a width W1 of the sound absorption chamber 4111 is greater than a width W2 of the connecting channel 4112. For example, in one of sub units 411, the sub unit 411 is a hollow cube, and the sound absorption chamber 4111 is a square chamber. The sub unit 411 includes a first surface 4113 and a second surface 4114 located opposite to each other, the first surface 4113 faces the sound permeable slot 413, and the second surface 4114 faces away from the sound permeable slot 413 and faces the sound absorption chamber 4111. The connecting channel 4112 is located at one side of the sound absorption chamber 4111 and spaced apart from two corners of the side of the sound absorption chamber 4111 by a same distance. The connecting channel 4112 extends from the second surface 4114 to the first surface 4113. One of the connecting channels 4112 located at the first side 4131 is located opposite to one of the connecting channels 4112 located at the second side 4132. The sound absorption chambers 4111 of all of the sub units 411 communicate with the opposite end portions 4135 of the same sound permeable slot 413 through the connecting channels 4112. The sub units 411 may be Helmholtz resonators. When sound waves pass through the sound permeable slot 413 and enter the sound absorption chambers 4111 via the connecting channels 4112, the sound waves will resonate at a specific frequency, thereby absorbing and dissipating sound energy.

In this embodiment, the sound absorption structure 40 is disposed between the hard disk storage area 11 and the fan storage area 12, the sub units 411 of the sound absorption unit 41 of the sound absorption structure 40 are arranged in the array and connected to one another to surround the sound permeable slot 413 together, the sound absorption chamber 4111 of each sub unit 411 is a polygonal chamber, and the connecting channel 4112 of each sub unit 411 communicates with the sound absorption chamber 4111 and is spaced apart from the corners of the sound absorption chamber 4111, and the sound absorption chamber 4111 of at least one of the sub units 411 communicates with the sound permeable slot 413 through the connecting channel 4112. By the aforementioned configuration, when sound generated by the fan module 30 enters the sound absorption chamber 4111 via the connecting channel 4112 of the sub unit 411, the sound waves cause resonance within the sound absorption chamber 4111, converting sound energy into kinetic energy through resonance, thereby dissipating the sound. This effectively reduces the noise transmitted from the fan module 30 to the hard disk module 20, preventing the noise from affecting the performance of the hard disk module 20.

In addition, due to the configuration where one of the connecting channels 4112 on the first side 4131 is opposite to one of the connecting channels 4112 on the second side 4132, the sound absorption structure 40, when subjected to different strains, causes the resonant frequency to decrease and increases the range over which the resonant frequency can be adjusted, thereby enhancing the ability to control the resonant frequency.

Moreover, the connecting channel 4112 is located at one side of the sound permeable slot 413, and the sound absorption chamber 4111 is the square chamber, which can enhance the noise reduction capability. Additionally, the design of the sound absorption chamber 4111 as the square chamber increases the utilization of the structural space.

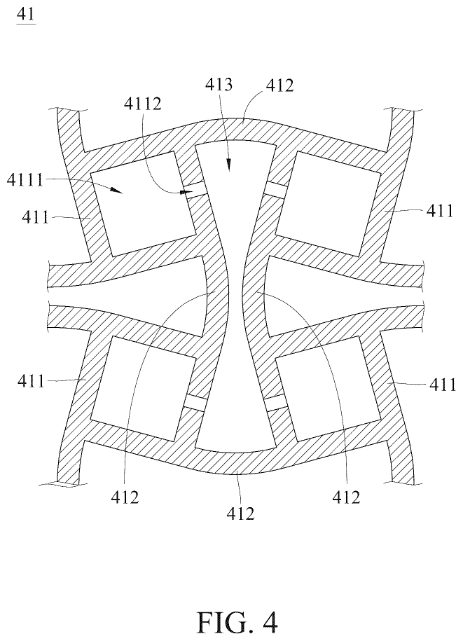

Previous studies observed that the performance of the hard disk module 20 deteriorates most significantly when the noise frequency is 3000 Hz. This may be because the noise at this frequency induces resonance within the hard disk, thereby affecting its read/write performance. In this embodiment, the sound absorption structure 40, in its undeformed state, can reduce noise at a frequency of approximately 2980 Hz, achieving a sound transmission loss (STL) greater than 5 dB, with a frequency bandwidth of 59 Hz. Furthermore, due to the negative Poisson's ratio characteristic of the planar auxetic material, applying different strains causes the sound absorption structure 40 to elastically deform. As a result, the sound absorption structure 40 can slightly adjust the applicable sound frequency for noise reduction under different stretching or compressing conditions. For example, referring to FIGS. 2 and 4, FIG. 4 is a schematic view of the deformed sound absorption unit in FIG. 3. After applying a strain of −0.1 to the sound absorption structure 40, the shape of the sound permeable slot 413 in the sound absorption unit 41 is compressed, allowing the sound absorption structure 40 to reduce noise at a frequency of approximately 2890 Hz, achieving a sound transmission loss (STL) greater than 5 dB, with a frequency bandwidth narrowed to 28 Hz. After applying a strain of 0.1 to the sound absorption structure 40, the shape of the sound permeable slot 413 in the sound absorption unit 41 is stretched, allowing the sound absorption structure 40 to reduce noise at a frequency of approximately 2890 Hz, achieving a sound transmission loss (STL) greater than 5 dB, with a frequency bandwidth maintained to 59 Hz. Specifically, after applying different strains, the noise reduction performance of the sound absorption structure 40 changes. Applying a positive strain shifts the resonance frequency of the sound absorption structure toward a lower frequency. In contrast, applying a negative strain reduces the effective frequency range of the sound absorption structure. Due to the configuration where the sound absorption structure 40 can elastically deform along the lengthwise direction L and the heightwise direction H, after compression deformation, the sound absorption structure 40 can concentrate noise reduction for lower frequencies (2900 Hz) within a narrower frequency range, while after stretching deformation, the sound absorption structure 40 can also provide noise reduction for lower frequencies (2900 Hz) and maintain the sound transmission loss (STL). This flexibility allows the sound absorption structure 40 to adjust its noise reduction performance according to specific needs, providing optimal noise reduction in various application scenarios.

In this embodiment, during the design process of the sound absorption structure 40, theoretical methods are used for calculations, coupled with numerical simulations for validation, allowing for the rapid design of the sound absorption structure 40 that meets the requirements and helps reduce costs. In this embodiment, the sound absorption structure 40 is a planar auxetic material combined with the application of Helmholtz resonators. Compared to conventional sound absorption structures, the sound absorption structure 40 offers multiple advantages, including resonant frequency control, adjustable noise reduction bandwidth, and the equivalent stress required for strain. Additionally, the sound absorption structure 40 is a monolithic structure, which simplifies the assembly of the sound absorption structure 40, further reducing costs.

In this embodiment, by combining the sub units 411 as Helmholtz resonators with planar auxetic materials exhibiting a negative Poisson's ratio, the configuration uses the advantage of planar auxetic materials being more easily deformable compared to conventional structures. Additionally, the structure allows for adjustment of ventilation rates, and its thickness is not affected by deformation, making it more suitable for application within the internal space of the server.

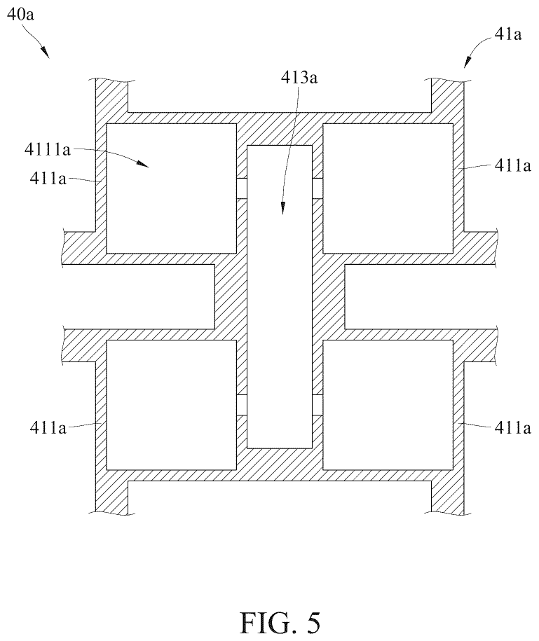

Then, referring to FIG. 5, FIG. 5 is a schematic view of a sound absorption unit of a sound absorption structure according to a second embodiment of the invention.

The sound absorption structure 40a of this embodiment is similar to the sound absorption structure 40 of the aforementioned embodiment. The following will primarily describe the differences between them, while the same parts will not be repeated.

Sound absorption chambers 4111a of sub units 411a in a sound absorption unit 41a of this embodiment are larger in size than the sound absorption chambers 4111 of the sub units 411 in the sound absorption unit 41 of the previous embodiment. Moreover, a sound permeable slot 413a surrounded by the sub units 411a in this embodiment is smaller than the sound permeable slot 413 surrounded by the sub units 411 in the previous embodiment.

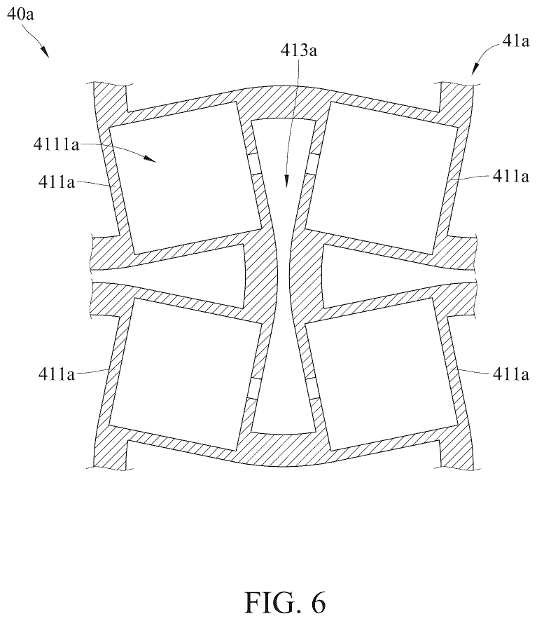

In this embodiment, the sound absorption structure 40a, in its undeformed state, can reduce noise at a frequency of approximately 3070 Hz, achieving a sound transmission loss (STL) greater than 5 dB, with a frequency bandwidth of 133 Hz. Furthermore, due to the negative Poisson's ratio characteristic of the planar auxetic material, applying different strains causes the sound absorption structure 40a to elastically deform. As a result, the sound absorption structure 40a can slightly adjust the applicable sound frequency for noise reduction under different stretching or compressing conditions. For example, referring to FIG. 6, FIG. 6 is a schematic view of the deformed sound absorption unit in FIG. 5. After applying a strain of −0.1 to the sound absorption structure 40a, the shape of the sound permeable slot 413a in the sound absorption unit 41a is compressed, allowing the sound absorption structure 40 a to reduce noise at a frequency of approximately 2980 Hz, achieving a sound transmission loss (STL) greater than 5 dB, with a frequency bandwidth extended to 256 Hz. After applying a strain of 0.1 to the sound absorption structure 40a, the shape of the sound permeable slot 413a in the sound absorption unit 41a is stretched, allowing the sound absorption structure 40 a to reduce noise at a frequency of approximately 3020 Hz, achieving a sound transmission loss (STL) greater than 5 dB, with a frequency bandwidth narrowed to 97 Hz. The sound absorption structure 40a is elastically deformable along the lengthwise direction and the heightwise direction thereof. Specifically, applying different strains shifts the sound absorption structure 40a toward lower frequency. Applying a negative strain increases the effective frequency range of the sound absorption structure, while applying a positive strain reduces the effective frequency range of the sound absorption structure. Moreover, by comparing the second embodiment with the first embodiment, it is evident that by enlarging the size of the sound absorption chamber 4111a, the frequency bandwidth of the sound absorption structure 40a is significantly increased under different conditions—whether in its original state, under stretching, or under compression. In other words, the sound absorption structure 40a of the second embodiment is capable of responding to signals in a wider frequency range, thereby exhibiting better noise reduction performance.

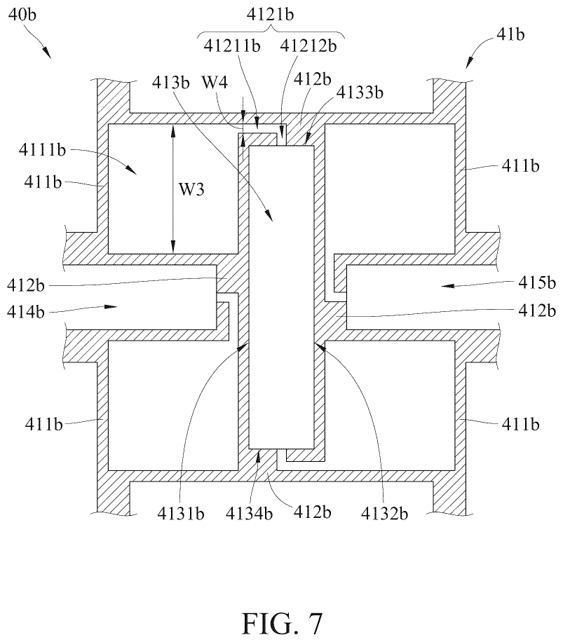

Then, referring to FIG. 7, FIG. 7 is a schematic view of a sound absorption unit of a sound absorption structure according to a third embodiment of the invention.

The sound absorption structure 40b of this embodiment is similar to the sound absorption structure 40 of the aforementioned embodiment. The following will primarily describe the differences between them, while the same parts will not be repeated.

In this embodiment, other two sound permeable slots 414b and 415b are respectively formed between two of four sub units 411b located at a first side 4131b of a sound permeable slot 413b and other two of the four sub units 411b located at a second side 4132b of the sound permeable slot 413b. The sub units 411b and connection portions 412b, for example, form a plurality of Helmholtz resonators, respectively. Each of the sub units 411b includes a sound absorption chamber 4111b, and each of the connection portions 412b includes a connecting channel 4121b.

The sound absorption chambers 4111b of the sub units 411b respectively communicate with the connecting channels 4121b of the connection portions 412b, and widths W3 of the sound absorption chambers 4111b are greater than widths W4 of the connecting channels 4121b. Take one of the sub units 411b and one of the connection portions 412b forming one Helmholtz resonator for instance, the sub unit 411b is a hollow cube, and the sound absorption chamber 4111b is a square chamber. The connecting channel 4121b of the connection portion 412b includes a first extension part 41211b and a second extension part 41212b connected to each other. The first extension part 41211b and the second extension part 41212b are, for example, perpendicular to each other. One end of the first extension part 41211b located farther away from the second extension part 41212b is, for example, connected to a corner of the sound absorption chamber 4111b. One of the connecting channels 4121b located at a third side 4133b of the sound permeable slot 413b is located opposite to another one of the connecting channels 4121b located at a fourth side 4134b of the sound permeable slot 413b. When sound waves pass through the sound permeable slots 413b, 414b and 415b and enter the sound absorption chambers 4111b via the connecting channels 4121b, the sound waves will resonate at a specific frequency, thereby absorbing and dissipating sound energy.

In this embodiment, the sound absorption chambers 4111b of two of the four sub units 411b located on a diagonal line communicate with the same sound permeable slot 413b through the connecting channels 4121b of two of the four connection portions 412b located at the third side 4133b and the fourth side 4134b of the sound permeable slot 413b. The sound absorption chambers 4111b of the other two of the sub units 411b located on another diagonal line respectively communicate with the other two sound permeable slots 414b and 415b through the connecting channels 4121b of two of the four connection portions 412b located at the first side 4131b and the second side 4132b of the sound permeable slot 413b. In other words, the connecting channels 4121b of the connection portions 412b respectively communicate with the sound absorption chambers 4111b of the sub units 411b.

Furthermore, because the connecting channels 4112b are provided in the connection portions 412b, which are the area of the sound absorption structure 40b where the structural deformation is greatest, and due to the configuration where one of the connecting channels 4121b on the third side 4133b is opposite to one of the connecting channels 4121b on the fourth side 4134b, the sound absorption structure 40b, when subjected to different strains, causes the resonant frequency to decrease and increases the range over which the resonant frequency can be adjusted, thereby enhancing the ability to control the resonant frequency. In this embodiment, the sound absorption structure 40b, in its undeformed state, can reduce noise at a frequency of approximately 3100 Hz, achieving a sound transmission loss (STL) greater than 5 dB, with a frequency bandwidth of 135 Hz.

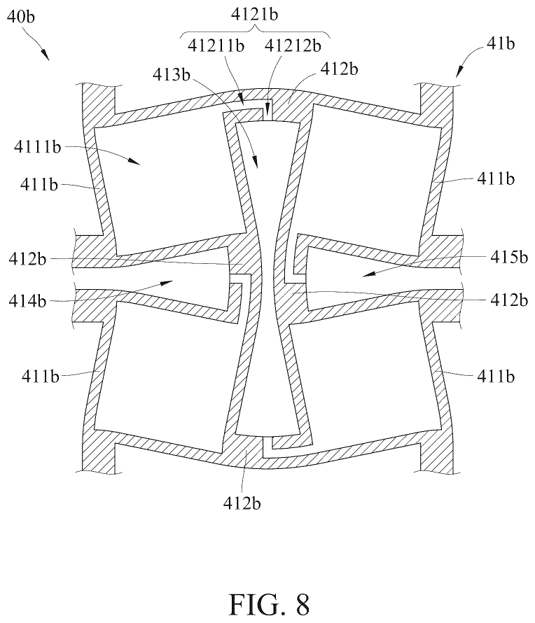

Furthermore, due to the negative Poisson's ratio characteristic of the planar auxetic material, applying different strains causes the sound absorption structure 40b to elastically deform. As a result, the sound absorption structure 40b can slightly adjust the applicable sound frequency for noise reduction under different stretching or compressing conditions. For example, referring to FIG. 8, FIG. 8 is a schematic view of the deformed sound absorption unit in FIG. 7. After applying a strain of −0.1 to the sound absorption structure 40b, the shape of the sound permeable slots 413b, 414b and 415b in the sound absorption unit 41b are compressed, allowing the sound absorption structure 40b to reduce noise at a frequency of approximately 2900 Hz, achieving a sound transmission loss (STL) greater than 5 dB, with a frequency bandwidth extended to 228 Hz. After applying a strain of 0.1 to the sound absorption structure 40b, the shape of the sound permeable slots 413b, 414b and 415b in the sound absorption unit 41b are stretched, allowing the sound absorption structure 40b to reduce noise at a frequency of approximately 3100 Hz, achieving a sound transmission loss (STL) greater than 5 dB, with a frequency bandwidth narrowed to 115 Hz.

It should be noted that the sound absorption structures in the above embodiments are not limited to being elastically deformable. In other embodiments, the sound absorption structure may be a non-deformable structure.

On the other hand, in the above embodiments, the sound absorption chambers of the sub units of the sound absorption unit communicate with the same sound permeable slot, but the invention is not limited thereto. In other embodiments, the sound absorption chambers of the sub units of the sound absorption unit may communicate with different sound permeable slots.

Furthermore, the shapes of the sound absorption units in the sound absorption structures of the above embodiments are not intended to limit the invention, but may be adjusted according to requirements.

According to the sound absorption structure and the server as discussed in the above embodiments, the sound absorption structure is disposed between the hard disk storage area and the fan storage area, the sub units of the sound absorption unit of the sound absorption structure are arranged in the array and connected to one another to surround the sound permeable slot together, the sound absorption chamber of each sub unit is a polygonal chamber, and the connecting channels of the sub units respectively communicate with the sound absorption chambers of the sub units, and the sound absorption chamber of at least one of the sub units communicates with the sound permeable slot through the connecting channel. By the aforementioned configuration, when sound generated by the fan module enters the sound absorption chamber via the connecting channel of the sub unit, the sound waves cause resonance within the sound absorption chamber, converting sound energy into kinetic energy through resonance, thereby dissipating the sound. This effectively reduces the noise transmitted from the fan module to the hard disk module, preventing the noise from affecting the performance of the hard disk module.

In addition, the configuration of the sound absorption structure that can elastically deform along the lengthwise and heightwise directions allows the sound absorption structure to provide noise reduction for different frequencies of sound.

Moreover, during the design process of the sound absorption structure, theoretical methods are used for calculations, coupled with numerical simulations for validation, allowing for the rapid design of the sound absorption structure that meets the requirements and helps reduce costs. Furthermore, the sound absorption structure is a monolithic structure, which simplifies the assembly of the sound absorption structure, further reducing costs.

In one embodiment of the invention, the server of the invention can be used for artificial intelligence (AI) computing, edge computing, as well as 5G server, cloud server, or vehicle-to-everything (V2X) server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A sound absorption structure, comprising:
at least one sound absorption unit, comprising a plurality of sub units and a plurality of connection portions, wherein the plurality of sub units are arranged in an array and connected to one another via the plurality of connection portions to surround a sound permeable slot together;
wherein each of the plurality of sub units comprises a sound absorption chamber, the sound absorption chamber is a polygonal chamber; wherein at least one of the plurality of sub units or at least one of the plurality of connection portions comprises a connecting channel, and the sound absorption chamber communicates with the sound permeable slot through the connecting channel.

2. The sound absorption structure according to claim 1, wherein the plurality of sub units comprises four sub units, the plurality of connection portions comprises four connection portions, the four sub units are arranged in a 2×2 array, the sound permeable slot is rectangular and comprises a first side, a second side, a third side and a fourth side, the first side is located opposite to the second side, the third side is located opposite to the fourth side, two of the four sub units and one of the four connection portions are located at the first side of the sound permeable slot, the other two of the four sub units and another one of the four connection portions are located at the second side of the sound permeable slot, and the other two of the four connection portions are respectively located at the third side and the fourth side of the sound permeable slot.

3. The sound absorption structure according to claim 2, wherein the sound absorption chambers of the four sub units are connected to two opposite end portions of the sound permeable slot via the connecting channels.

4. The sound absorption structure according to claim 2, wherein at least one of the four sub units comprises the connecting channel, the connecting channel is located at one side of the sound absorption chamber and is spaced apart from two corners of the side of the sound absorption chamber by a same distance.

5. The sound absorption structure according to claim 2, wherein at least one of the four sub units comprises the connecting channel, each of the four sub units comprises a first surface and a second surface located opposite to each other, the first surface faces the sound permeable slot, the second surface faces away from the sound permeable slot and faces the sound absorption chamber, the connecting channel extends from the second surface to the first surface.

6. The sound absorption structure according to claim 1, wherein the plurality of sub units and the plurality of connection portions respectively form a plurality of Helmholtz resonators.

7. The sound absorption structure according to claim 1, wherein the sound absorption structure is elastically deformable in a lengthwise direction and a heightwise direction thereof.

8. The sound absorption structure according to claim 2, wherein each of the plurality of connection portions comprises the connecting channel, the sound absorption chambers of two of the four sub units located on a diagonal line communicate with the sound permeable slot through the connecting channels of two of the four connection portions located at the third side and the fourth side of the sound permeable slot.

9. The sound absorption structure according to claim 8, wherein other two sound permeable slots are formed between two of the four sub units located at the first side of the sound permeable slot and between the other two of the four sub units located at the second side of the sound permeable slot; and the sound absorption chambers of the other two of the sub units located on another diagonal line respectively communicate with the other two sound permeable slots through the connecting channels of two of the four connection portions located at the first side and the second side of the sound permeable slot.

10. The sound absorption structure according to claim 9, wherein the connecting channel of each of the four connection portions comprises a first extension part and a second extension part connected to each other, and the first extension part and the second extension part are perpendicular to each other.

11. The sound absorption structure according to claim 10, wherein the connecting channels of the four connection portions are respectively connected to corners of the sound absorption chambers of the four sub units.

12. A server, comprising:
a casing, comprising a hard disk storage area and a fan storage area;
a hard disk module, disposed in the hard disk storage area;
a fan module, disposed in the fan storage area; and
a sound absorption structure, disposed between the hard disk storage area and the fan storage area and comprising:
at least one sound absorption unit, comprising a plurality of sub units and a plurality of connection portions, wherein the plurality of sub units are arranged in an array and connected to one another via the plurality of connection portions to surround a sound permeable slot together;
wherein each of the plurality of sub units comprises a sound absorption chamber, the sound absorption chamber is a polygonal chamber; wherein at least one of the plurality of sub units or at least one of the plurality of connection portions comprises a connecting channel, and the sound absorption chamber communicates with the sound permeable slot through the connecting channel.
